(19) United States
(12) Patent Application Publication
(10) Pub. No.: US 2009/0260868 A1
(43) Pub. Date: Oct. 22, 2009

(54) Printed circuit board and method of manufacturing the same

(75) Inventors: Chang Gun Oh, Gyunggi-do (KR); Mi Sun Hwang, Gyunggi-do (KR); Suk Won Lee, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/215,413

(22) Filed: Jun. 27, 2008

(30) Foreign Application Priority Data
Apr. 18, 2008 (KR) 10-2008-0036182

(51) Int. Cl. H05K 1/00; H05K 3/42

(52) U.S. Cl. 174/262; 29/852

(57) ABSTRACT

The printed circuit board includes the via formed with the electroplating layer unlike a conventional via formed with an electroless plating layer and an electroplating layer and having a cylindrical shape, and thus exhibits good interlayer electrical connection and high reliability of physical contact upon thermal stress caused by the variance in physical properties of material depending on changes in temperature. The via has no upper land, and thus a fine circuit pattern of the circuit layer can be formed on the via.

### CROSS REFERENCE TO RELATED APPLICATION

This application claims the benefit of Korean Patent Application No. 10-2008-0036182, filed Apr. 18, 2008, entitled “Printed circuit board and method for manufacturing the same”, which is hereby incorporated by reference in its entirety into this application.

### BACKGROUND OF THE INVENTION

1. Field of the Invention

The present invention relates to a printed circuit board (PCB) and a method of manufacturing the same, and more particularly, to a PCB, which includes a via formed with an electroplating layer, without an electroless plating layer, thus realizing interlayer connection.

2. Description of the Related Art

Generally, a PCB is manufactured by attaching a thin film made of copper or the like to either surface of an insulating plate made of phenol resin or epoxy resin, etching the insulating plate with the thin film according to a wiring pattern of a circuit (such that portions other than the linear circuit are eliminated) to thus obtain a required circuit, and then boring holes for mounting parts.

That is, the PCB functions to electrically interconnect the mounting parts through the wiring pattern, and further, the PCB serves to supply electricity to the parts and mechanically support the parts.

Examples of the PCB include a single-sided PCB, in which a wiring pattern is formed on only one surface of an insulating substrate, a double-sided PCB, in which a wiring pattern is formed on both surfaces of an insulating substrate, and an MLB (Multi-Layered Board) in which a multilayer wiring pattern is formed. In the past, because devices were uncomplicated and circuit patterns were simple, single-sided PCBs were used. However, recently, as circuits become increasingly complicated and the demand for high-density and small circuits is increasing, double-sided PCBs or MLBs are mainly used.

The MLB is formed by alternately stacking circuit layers and insulating layers. In this structure, in order to interconnect an inner circuit layer and an outer circuit layer, there is a need for a via to electrically interconnect the inner circuit layer and the outer circuit layer while passing through the insulating layer. The case where an MLB is manufactured through a build-up process essentially involves a process of forming a via hole in the insulating layer provided on the completed inner circuit layer so as to realize electrical connection between-the inner circuit layer and the outer circuit layer.

Conventionally, in the case where the MLB is manufactured through a build-up process, the insulating layer is provided on the inner circuit layer and a portion of the inner circuit layer where a via is to be formed is subjected to laser machining, thus forming a via hole. However, as shown in FIG. 1, in the case where the via hole 3 is formed through laser machining, the shape of the via hole 3 is truncated conical due to the characteristic of the laser, and thus the diameter of the via hole 3 is decreased toward the inner circuit layer 1. The via hole 3 having such a shape is disadvantageous because it has physical properties inferior to those of a via hole having a constant diameter.

Further, the via is conventionally formed by subjecting the via hole having the above shape to fill-electroplating or filling using a conductive paste. The via conventionally formed through fill-electroplating is required to have a land 5 larger than the width of the circuit pattern in consideration of process error because via hole plating and pattern plating are performed at the same time. Due to the presence of the land 5, it is difficult to increase the density of the circuit pattern near the via. Furthermore, the conductive paste prepared by mixing metal powder with resin material is dissatisfactory because its electrical signal transfer performance is inferior to that of metal.

### SUMMARY OF THE INVENTION

Therefore, the present invention has been made keeping in mind the above problems encountered in the related art, and provides a PCB and a method of manufacturing the same, in which a via is formed with an electroplating layer and has a cylindrical shape, thus realizing good interlayer electrical connection.

In addition, the present invention provides a PCB and a method of manufacturing the same, in which the line width of a circuit pattern, which is connected to the upper portion of a via, is formed to be smaller than the diameter of the via, thus realizing a high-density circuit pattern.

According to the present invention, a PCB may comprise an insulating layer, a land formed under the insulating layer, a circuit pattern formed on the insulating layer, and a via for electrically connecting the land and the circuit pattern, wherein the land includes a seed layer and a first electroplating layer having one surface in contact with the seed layer and the other surface connected to the via, and the via is formed with a second electroplating layer.

In the present invention, the via may have a cylindrical shape.

In the present invention, the width of the circuit pattern may be smaller than the diameter of the via.

In addition, according to the present invention, a method of manufacturing a PCB may comprise (A) forming a seed layer on an entire surface of a core substrate having an insulating material; (B) forming a first resist layer, having an opening for a first circuit layer including a land of a via, on the seed layer; (C) plating the opening, thus forming the first circuit layer; (D) forming a second resist layer having a via hole on the first circuit layer so that the land is exposed; (E) plating the via hole, thus forming a via; (F) removing the first resist layer and the second resist layer, and exposing the insulating material of the core substrate corresponding to a portion where the first circuit layer is not provided; (G) forming an insulating layer on the first circuit layer; and (H) forming a second circuit layer, including a circuit pattern which is connected to an upper surface of the via, on the insulating layer.

In the present invention, in (H), the line width of the circuit pattern which is connected to the upper surface of the via may be smaller than the diameter of the via.

In the present invention, the method may further comprise removing a portion of the insulating layer in a thickness direction so that the upper surface of the via is exposed from the insulating layer, after forming the insulating layer.

In the present invention, the second resist layer may have a thickness greater than 30 μm.

In the present invention, the core substrate may be a resin substrate, a single-sided laminate, or a double-sided laminate.

In the present invention, (A) to (H) may be performed using a substrate manufactured through (A) to (G) as the core substrate in (A).

### BRIEF DESCRIPTION OF THE DRAWINGS

The features and advantages of the present invention will be more clearly understood from the following detailed description taken in conjunction with the accompanying drawings, in which:

FIG. 1 is a cross-sectional view illustrating a conventional PCB including a via hole formed through laser machining;

FIG. 2 is a cross-sectional view illustrating the PCB according to the present invention; and

FIGS. 3A to 3N are cross-sectional views sequentially illustrating the process of manufacturing the PCB according to the present invention.

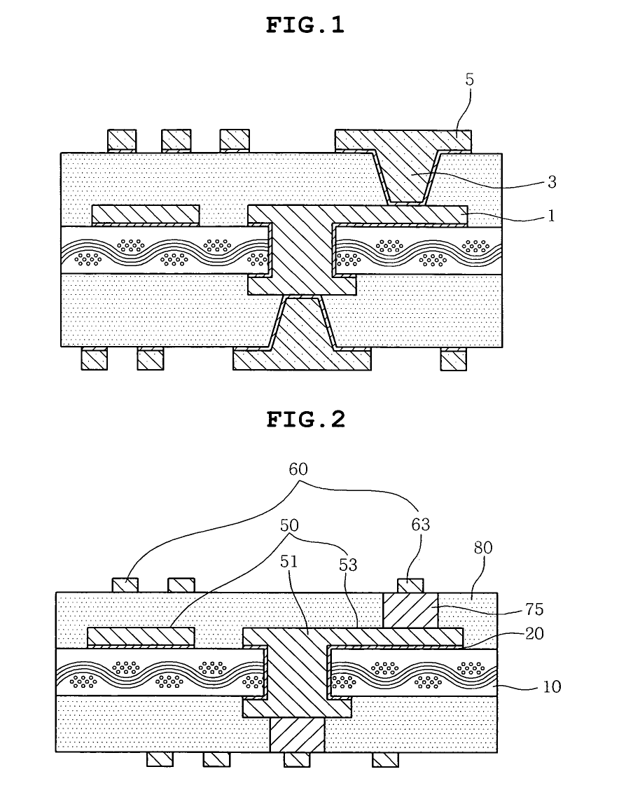

### DESCRIPTION OF THE PREFERRED EMBODIMENTS

Hereinafter, a detailed description will be given of a PCB and a method of manufacturing the same according to the present invention, with reference to the appended drawings. Throughout the drawings, like reference numerals refer to like elements, and redundant descriptions are omitted. In the description, the terms “first”, “second” and so on are used to distinguish one element from another element, but are not to be construed to limit the elements. Further, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

FIG. 2 is a cross-sectional view illustrating the PCB according to the present invention. As illustrated in FIG. 2, the PCB according to the present invention includes an insulating layer 80, a land 53 formed under the insulating layer 80, a circuit pattern 63 formed on the insulating layer 80, and a via 75 for electrically connecting the land 53 and the circuit pattern 63.

The land 53 includes a seed layer 20 and a first electroplating layer 51 formed on the seed layer 20.

The via 75 functions to electrically connect the land 53 and the circuit pattern 63, in which the insulating layer 80 is disposed therebetween. The via 75 is formed with a second electroplating layer, and is connected to the upper surface of the first electroplating layer 51 of the land 53, that is, to the surface of the first electroplating layer 51 of the land 53, which is not in contact with the seed layer 20. The via 75 has a constant diameter with a cylindrical shape, and the outer circumferential surface of the via 75 is perpendicular to the contact surface of the land 53.

The circuit pattern 63 is a conductive line in surface contact with the upper surface of the via 75. The circuit pattern 63 is in surface contact with the upper surface of the via 75 across the via 75. The line width of the circuit pattern 63 is smaller than the diameter of the via 75 connected therewith. However, the shape of the circuit pattern 63 according to the present invention is not limited to this shape, and it should be noted that the formation of a circuit pattern 63 having a width greater than or equal to the diameter of the via 75 is possible.

As mentioned above, because the via 75 according to the present invention is formed with a second electroplating layer and has a cylindrical shape, it has electrical properties superior to those of a via having the same volume as the via 75 of the invention but having a different shape and made of different material.

Further, because the via 75 according to the present invention has no upper land, a fine circuit pattern 63 can be formed on the via 75. Moreover, the circuit pattern 63 is in surface contact with the upper surface of the via 75 across the via 75, and thus, electrical connection is better than a conventional PCB having a circuit pattern connected to the inner plating layer of the via 75.

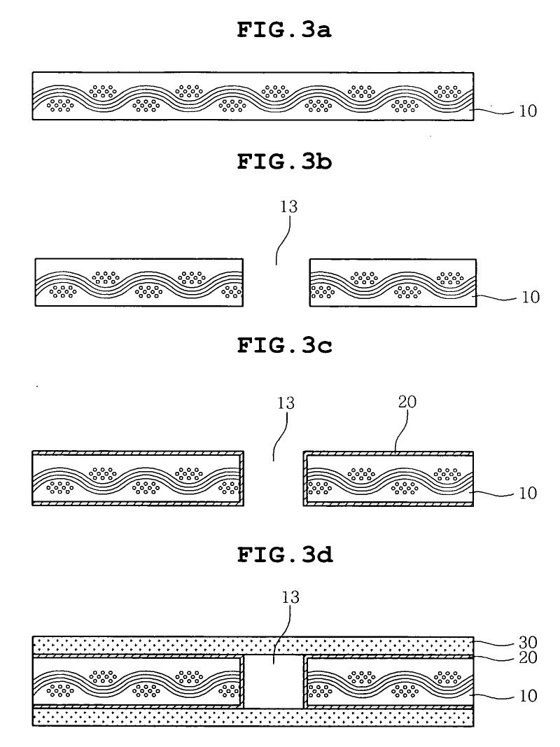

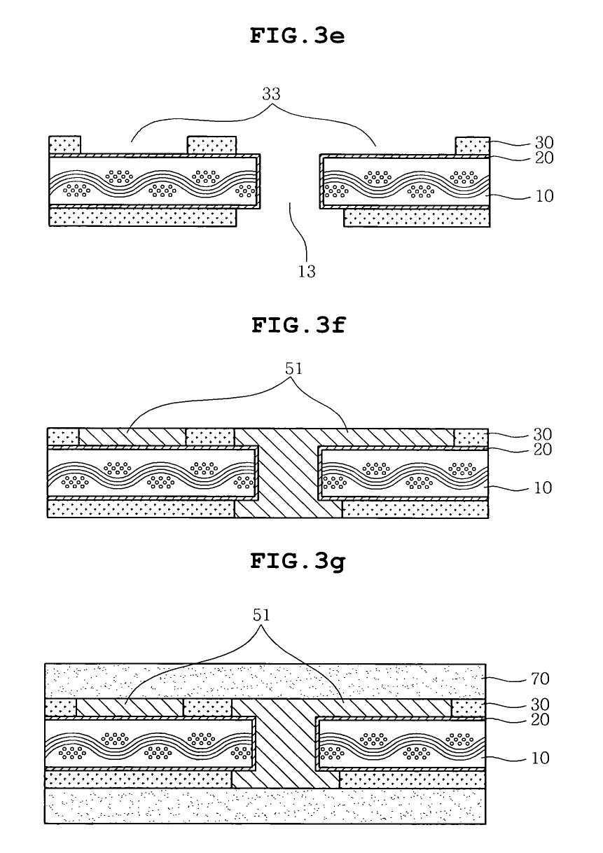

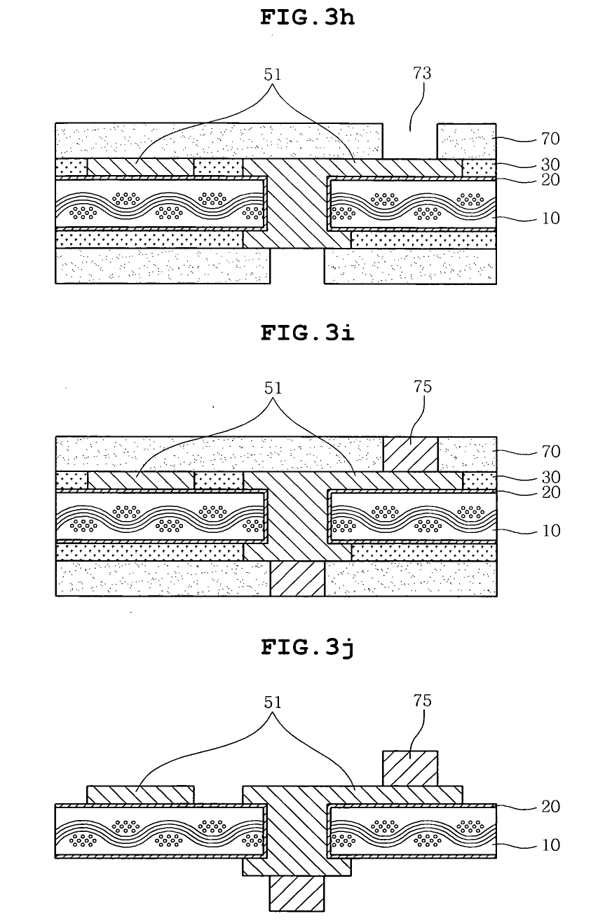

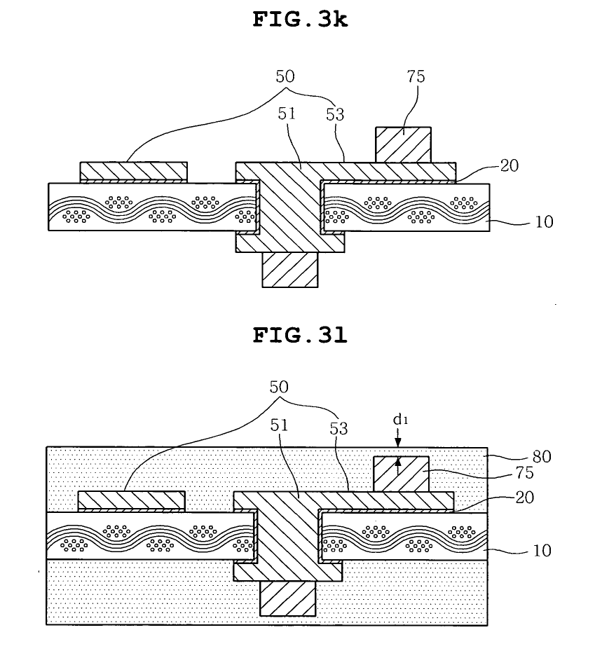

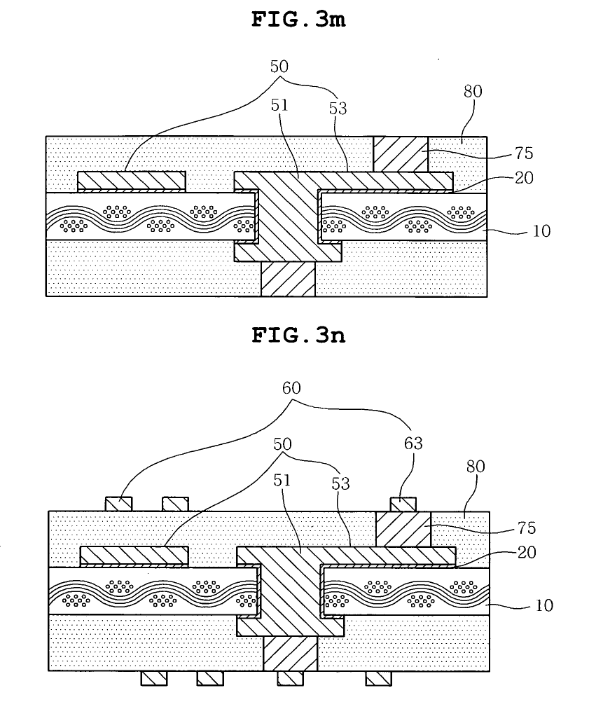

Below, the method of manufacturing the PCB according to the present invention is described. FIGS. 3A to 3N sequentially illustrate the process of manufacturing the PCB according to the present invention.

First, a first circuit layer 50 is formed through a semi-additive process (SAP) or a modified semi-additive process (MSAP). Here, the procedure for forming the first circuit layer 50 through SAP is briefly described.

As shown in FIG. 3A, a core substrate 10 is provided, and a through hole 13 is formed in the core substrate 10 (FIG. 3B). The core substrate 10 is a plate with an insulating material, and includes a resin substrate, a single-sided laminate, and a double-sided laminate. That is, in the present invention, the use of a resin substrate as the core substrate 10 is illustrated and described. However, the present invention is not limited thereto, and it is possible to use a copper clad laminate having a copper foil 1˜3 μm thick, in addition to the resin substrate, as the core substrate 10.

Next, as shown in FIG. 3C, the entire surface of the core substrate 10 is subjected to electroless copper plating, thus forming a seed layer 20 on the surface of the core substrate 10 and the inner wall of the through hole 13. The formation of the seed layer 20 is performed through a catalyst deposition process including cleaning, soft etching, pre-catalysis, catalysis, acceleration, electroless copper plating, and oxidation prevention.

Next, as shown in FIG. 3D, a photosensitive resist film is applied on the seed layer 20, thus forming a first resist layer 30, which is then subjected to exposure and development, thus forming an opening 33 for the first circuit layer 50 (FIG. 3E). A photomask printed with the pattern of the first circuit layer 50 is brought into close contact with the upper surface of the first resist layer 30, and is then irradiated with UV light. As such, UV light is passed through the non-printed portion of the photomask, thus forming a cured portion in the first resist layer 30 under the photomask, whereas UV light is not passed through the black printed portion of the photomask, thus forming an uncured portion in the first resist layer 30 under the photomask. The photomask is then removed, after which development is conducted so that the cured portion of the first resist layer 30 remains, thus removing the uncured portion of the first resist layer 30, thereby forming the opening 33.

Next, as shown in FIG. 3F, copper electroplating is performed, thus forming a copper electroplating layer 51. The copper electroplating is carried out using the cured portion of the first resist layer 30 as a plating resist, thereby forming the first electroplating layer 51 on the seed layer 20. In the present invention, the process of forming the first electroplating layer 51 is performed using a direct current (DC) rectifier after a substrate has been dipped into a copper plating bath. Such copper electroplating is preferably carried out by calculating the plating area and then applying a predetermined current required to plate the calculated plating area using the DC rectifier, to deposit copper.

Next, as shown in FIG. 3G, a photosensitive resist is applied on the copper electroplating layer 51 and the first resist layer 30, thus forming a second resist layer 70. In consideration of the interlayer interval of the substrate and the reliability of the process of manufacturing the substrate, in a preferred embodiment of the present invention, the second resist layer 70 is formed to a thickness of 30 μm or more.

Next, as shown in FIG. 3H, the second resist layer 70 is subjected to exposure and development so that the portion of the copper electroplating layer 51 corresponding to the land is exposed, thus forming a via hole 73. Because the via hole 73 in the second resist layer 70 is formed through exposure and development of the second resist layer as the photosensitive resist film, the via hole 73 has a cylindrical shape in which the diameter thereof is not decreased even near the land 53. This is distinguished from a conventional via hole having a truncated conical shape formed by stacking an insulating layer 80 on a lower pattern and then performing laser machining.

Next, as shown in FIG. 3I, copper electroplating is performed, thus forming a via 75 in which the via hole 73 in the second resist layer 70 is filled only with an electroplating layer. The electroplating layer constituting the via 75 is referred to as a “second electroplating layer” to distinguish it from the first electroplating layer 51 for the first circuit layer 50. The copper plating process is advantageous because the physical properties of the copper plating layer are superior to those of the electroless plating layer and a thick copper plating layer may be easily formed. In the present invention, as the lead wire for copper electroplating, the seed layer 20 is used, thereby eliminating the formation of additional lead wire.

The via 75 thus formed has a cylindrical shape. Because the via 75 has a cylindrical shape in which the diameter of the upper surface thereof is the same as that of the lower surface thereof, electrical connection can be more efficiently realized compared to a via having a truncated conical shape. Further, the via 75 is formed with only the second electroplating layer, and thus electrical connection can be more efficiently realized compared to a via formed using a conductive paste comprising metal powder and a binder, such as epoxy resin, phenol resin, saturated polyester resin, unsaturated polyester resin, or polyurethane resin, which will be readily understood by one skilled in the art.

Next, as shown in FIG. 3J, the second resist layer 70 and the first resist layer 30 are removed, and the exposed portion of the seed layer 20 is removed through flash etching, thereby completing the first circuit layer 50 (FIG. 3K). If a copper clad laminate is used as the core substrate 10, the seed layer and the copper foil corresponding to the portion where the first circuit layer is not provided are removed, thus exposing the insulating material of the core substrate 10.

Next, as shown in FIG. 3L, an insulating layer 80 is formed on the first circuit layer 50. The insulating layer 80 is formed to be higher than the upper surface of the via 75 so that it slightly covers the upper surface of the via 75. The thickness d1 of the insulating layer 80 on the via 75 is set to 2˜3 μm.

Next, as shown in FIG. 3M, chemical desmearing is performed to remove the portion of the insulating layer 80 in the thickness direction, so that the upper surface of the via 75 is exposed. For example, the surface of the insulating layer 80 is removed using KMnO₄ and desmearing treatment is performed to increase the force of adhesion to the insulating layer 80 upon chemical copper plating.

Next, as shown in FIG. 3N, a second circuit layer 60 with a circuit pattern 63 which is connected to the via 75 is formed on the insulating layer 80, thereby completing the PCB. In the present invention, the second circuit layer is formed through SAP. As such, because the via 75 is already formed, the line width of the circuit pattern 63 of the second circuit layer 60 in contact with the via 75 may be formed to be smaller than the diameter of the via 75. That is, even when the width of the circuit pattern 63 formed on the via 75 is smaller than the diameter of the via 75, a highly reliable via 75 can be formed.

The present invention illustrates and describes the formation of one circuit layer on the core substrate 10, but is not limited thereto, and additional circuit layer formation is possible in the manner described in the specification. That is, a substrate having the above insulating layer 80 and subjected to desmearing is used as the core substrate in the beginning of the manufacturing process of the present invention, thereby additionally forming two or more circuit layers.

As described hereinbefore, the present invention provides a PCB and a method of manufacturing the same. In the PCB according to the present invention, a via is formed with an electroplating layer and has a cylindrical shape, thus realizing good interlayer electrical connection, and also, the area of the end portion thereof is large, thus exhibiting high physical stability depending on the thermal change.

Further, because the via of the PCB according to the present invention has no upper land, a fine circuit pattern of the circuit layer can be formed on the via.

In addition, in the method of manufacturing the PCB according to the present invention, the first circuit layer and the via are electroplated using the same seed layer as a lead wire, thus simplifying the manufacturing process. Moreover, laser machining for forming the via is obviated, thus reducing the manufacturing cost.

Although the preferred embodiments of the present invention have been disclosed for illustrative purposes, those skilled in the art will appreciate that various modifications, additions and substitutions are possible within the technical spirit of the invention.

What is claimed is:

1. A printed circuit board, comprising an insulating layer, a land formed under the insulating layer, a circuit pattern formed on the insulating layer, and a via for electrically connecting the land and the circuit pattern,
wherein the land includes a seed layer and a first electroplating layer having one surface in contact with the seed layer and the other surface connected to the via, and the via is formed with a second electroplating layer.

2. The printed circuit board as set forth in claim 1, wherein the via has a cylindrical shape.

3. The printed circuit board as set forth in claim 1, wherein a width of the circuit pattern is smaller than a diameter of the via.

4. A method of manufacturing a printed circuit board, comprising:
(A) forming a seed layer on an entire surface of a core substrate having an insulating material;
(B) forming a first resist layer, having an opening for a first circuit layer including a land of a via, on the seed layer,
(C) plating the opening, thus forming the first circuit layer,
(D) forming a second resist layer having a via hole on the first circuit layer so that the land is exposed;
(E) plating the via hole, thus forming a via;
(F) removing the first resist layer and the second resist layer, and exposing the insulating material of the core substrate corresponding to a portion where the first circuit layer is not provided;
(G) forming an insulating layer on the first circuit layer; and
(H) forming a second circuit layer, including a circuit pattern which is connected to an upper surface of the via, on the insulating layer.

5. The method as set forth in claim 4, wherein, in the (H), a line width of the circuit pattern which is connected to the upper surface of the via is smaller than a diameter of the via.

6. The method as set forth in claim 4, further comprising removing a portion of the insulating layer in a thickness direction so that an upper surface of the via is exposed from the insulating layer, after forming the insulating layer.

7. The method as set forth in claim 4, wherein the second resist layer has a thickness greater than 30 μm.

8. The method as set forth in claim 4, wherein the core substrate is a resin substrate, a single-sided laminate, or a double-sided laminate.

9. The method as set forth in claim 4, wherein the (A) to the (H) are performed using a substrate manufactured through the (A) to the (G) as the core substrate in the (A).
